(19) United States
(12) Patent Application Publication
(10) Pub. No.: US 2026/0191065 A1
(43) Pub. Date: Jul. 2, 2026

(54) MODIFIED SUBSTRATE AND METHODS FOR MANUFACTURING THE SAME

(71) Applicant: ETERNAL MATERIALS CO., LTD., KAOHSIUNG (TW)

(72) Inventors: Meng-Yen CHOU, KAOHSIUNG (TW); CHIA-JUNG HSU, KAOHSIUNG (TW); CHENG-HUNG CHIANG, KAOHSIUNG (TW); CHUNG-CHIEN HOU, KAOHSIUNG (TW)

(73) Assignee: ETERNAL MATERIALS CO., LTD., KAOHSIUNG (TW)

(21) Appl. No.: 19/388,995

(22) Filed: Nov. 13, 2025

(30) Foreign Application Priority Data
Dec. 31, 2024 (TW) 113151634
Mar. 31, 2025 (TW) 114112294

(51) Int. Cl. H01L 23/498; C08G 73/10; C08G 77/455; C09D 179/08; C09D 183/10; H01L 23/15

(52) U.S. Cl. CPC H10W 70/69; C08G 73/1042; C08G 73/106; C08G 73/1085; C08G 77/455; C09D 179/08; C09D 183/10; H10W 70/635; H10W 70/692

(57) ABSTRACT

The present invention provides a modified substrate, which comprises a substrate, a polyimide layer disposed on at least one of the surface of the substrate, and a patterned conductive material, wherein the patterned conductive material is disposed on the polyimide layer. The polyimide layer improves the adhesion of the conductive material to the substrate. The present invention also provides a method of producing a modified substrate, which comprises heating the substrate at a temperature of about 150° C. to about 350° C. to cure a polyimide precursor into polyimide to obtain a modified substrate. The present invention further provides use of a modified substrate as a glass intermediate layer, silicon intermediate layer or an IC carrier.

### FIELD OF THE INVENTION

The present invention relates to a modified substrate and methods for manufacturing the same.

### BACKGROUND OF THE INVENTION

Glass and glass ceramic have the characteristics of low dielectric loss, high resistivity, and resistance to bending. Therefore, when used in semiconductor packaging, glass substrates and glass ceramic substrates can provide advantages such as high frequency bandwidth density, high interconnection density, and high data transfer rates, and can significantly reduce energy loss in data transmission, which helps to package more electronic components on the same substrate. In addition, glass substrates and glass ceramic substrates also have application prospects in optical communications. Therefore, in recent years, in the semiconductor industry, high hopes are placed on glass substrates and glass ceramic substrates and many research and development efforts have been invested.

In order to achieve electrical communication with the electronic components and/or external power sources, through glass vias (TGV) can be formed in glass substrates or glass ceramic substrates. For example, a plurality of through holes that penetrate through upper and lower surfaces of the glass substrates or the glass ceramic substrates can be formed by etching or laser processing, and then conductive materials (usually copper) are filled into the through holes, thus forming the TGVs that electrically connect the upper and lower surfaces of the glass substrates or the glass ceramic substrates. In addition, various metal wiring designs can be implemented on the glass substrates or the glass ceramic substrates to obtain patterned conductive materials.

Glass metallization technology is one of the key processes in the art. One of the main researches in the glass metallization technology is a wet metal deposition process. In the wet metal deposition process, metal oxides are used as adhesion agents, which are first applied to a main surface of glass and walls of the through holes using a sol-gel method through wet coating, followed by sintering to cure the adhesion agents; and then, a metal seed layer is deposited by electroless plating, and the TGVs and metal wirings are prepared by electroplating and patterning processes. The sintering temperature is approximately at least 300° C. to 500° C., and the thermal treatment is carried out approximately for at least 30 min. The thermal stress generated at this high temperature is prone to cause micro-cracks in the glass. In addition, the metal oxides currently used as the adhesion agents are usually zinc oxide, tin oxide, or manganese oxide, which cannot be universally applied to different types of glass, and there are concerns about their stability. Especially in subsequent metal patterning processes, acidic etching solutions easily erode the metal oxides when etching the metal to form a desired circuit pattern, and the adhesion between the exposed metal oxides and subsequent applied build-up materials (such as resins) may deteriorate.

Silicon substrates, commonly used in the field of semiconductor technology, can also be adopted, and Through Silicon Vias (TSVs) can be formed in the silicon substrates. For example, a plurality of through holes that penetrate through upper and lower surfaces of the silicon substrates can be formed by etching or laser processing, and then conductive materials (usually copper) are filled into the through holes, thus forming the TSVs that electrically connect the upper and lower surfaces of the silicon substrates. In addition, various metal wiring designs can be further implemented on the silicon substrates to obtain the patterned conductive materials. However, there are also problems about adhesion and stability between the silicon substrate and the conductive materials.

In view of the above technical problems, it is expected to develop better substrate (such as glass substrate, glass ceramic substrate or silicon substrate) metallization technology and materials that help substrate metallization.

### SUMMARY OF THE INVENTION

The present invention provides a modified substrate and methods for manufacturing the same. Specifically, the present invention relates to a modified substrate, which includes a substrate, a polyimide layer disposed on a surface of the substrate, and a patterned conductive material, wherein the patterned conductive material is disposed on the polyimide layer. The substrate is selected from the group consisting of a glass substrate, a glass ceramic substrate, and a silicon substrate. Preferably, the polyimide layer comprises (i) a diamine residue selected from a nitrogen-containing heteroaromatic ring containing at least two nitrogen atoms, an aromatic ring or heterocyclic ring containing at least two —COOH groups, and a combination thereof, and (ii) a

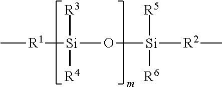

group, where, R¹, R², R³, R⁴, R⁵, R⁶ and m are as defined herein.

The present invention further relates to a method for manufacturing a modified substrate, which includes providing a substrate selected from the group consisting of a glass substrate, a glass ceramic substrate, and a silicon substrate; applying a polyimide precursor on at least one surface of the substrate, wherein the polyimide layer comprises (i) a diamine residue selected from a nitrogen-containing heteroaromatic ring containing at least two nitrogen atoms, an aromatic ring or heterocyclic ring containing at least two —COOH groups, and a combination thereof, and (ii) a

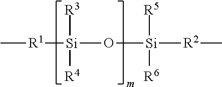

group; and heating at a temperature between about 150° C. and 350° C. to cure the polyimide precursor into polyimide to obtain the modified substrate.

The present invention further relates to use of the modified substrate as a glass intermediate layer (or glass interposer), a silicon intermediate layer (or silicon interposer), or an IC carrier.

In order to make the above objectives, technical features, and advantages of the present invention more clear and comprehensible, detailed description is given below by way of some specific samples.

### BRIEF DESCRIPTION OF THE DRAWINGS

FIG. 1 shows a substrate modification structure according to an embodiment of the present invention.

FIG. 2 shows a substrate modification method and a metallization process according to an embodiment of the present invention.

FIG. 3 is a schematic diagram of a peel strength test sample according to an embodiment of the present invention.

### DETAILED DESCRIPTION OF THE INVENTION

To facilitate understanding of the disclosures presented herein, several terms are defined below.

The term “about” refers to the acceptable margin of error for a specific value determined by those skilled in the art, which partly depends on how the value is measured or determined.

The term “alkyl” refers to a saturated linear or branched hydrocarbon group, preferably having 1 to 6 carbon atoms, more preferably 1 to 4 carbon atoms, and most preferably 1 to 3 carbon atoms. Embodiments include (but are not limited to): methyl, ethyl, n-propyl, isopropyl, n-butyl, isobutyl, tert-butyl, n-pentyl, neopentyl, n-hexyl, etc.

The term “alkenyl” refers to an unsaturated linear or branched hydrocarbon group that has at least one carbon-carbon double bond, preferably having 2 to 10 carbon atoms, and more preferably 3 to 8 carbon atoms. Embodiments include (but are not limited to) vinyl, allyl, methacrylyl, isopropenyl, pentenyl, hexenyl, heptenyl, 1-propenyl, 2-butenyl, 2-methyl-2-butenyl, and an analogous group thereof.

The term “aryl” refers to an aromatic ring system having 6 to 14 carbon atoms, such as a 6-carbon monocyclic, 10-carbon bicyclic- or 14-carbon tricyclic aromatic ring system. Embodiments of the aryl include (but are not limited to) phenyl, tolyl, naphthyl, fluorenyl, anthracyl, phenanthryl, and an analogous group thereof.

The term “heterocyclic group” refers to a saturated, partially saturated (e.g., those named with prefixes such as dihydro, trihydro, tetrahydro, hexahydro, etc.), or unsaturated 3 to 14 membered cyclic group consisting of carbon atoms and at least one heteroatom selected from N, O, or S, preferably a 4 to 10 membered cyclic group, and more preferably a 5 to 6 membered cyclic group. Preferably, the groups have 1 to 4 heteroatoms, and more preferably 1 to 3 heteroatoms. Embodiments include a 5 or 6 membered heterocyclic group having 1 to 3 heteroatoms selected from N, O, or S. In the present invention, the heterocyclic group may be a monocyclic, bicyclic, or tricyclic ring system, which includes a fused ring (e.g., fused with another heterocycle or another aromatic carbon ring to form the fused ring).

Each embodiment and example of the present invention disclosed in this specification can be individually combined with all other embodiments and examples of the present invention, covering all possible combinations.

The substrate, polyimide material, metallization process, application and modified substrate will be described below, respectively.

### Substrate

The substrate of the present invention is selected from the group consisting of a glass substrate, a glass ceramic substrate, and a silicon substrate. According to some embodiments, the substrate of the present invention is a glass substrate.

The main component of glass is silicon dioxide. Other components, such as metal or metal oxide, can be contained as needed. The proportion of each component is adjusted according to needed properties (such as color or heat resistance). The type of glass is not limited. In some embodiments, the polyimide material of the present invention is suitable for any type or most types of glass without special limitation.

Glass has the advantages of low dielectric constant, high resistivity, resistance to bending, low cost, etc., and can play a role in heat dissipation to a certain extent. In addition, due to high light transmittance, the glass is suitable for optical electronic components and has application prospects in optical communication.

Glass ceramic mainly contains glass, and contains a crystalline phase component, a fluxing agent and/or other additives, and can also be prepared by co-firing glass powder and ceramic powder. The glass ceramic has the advantages of both glass and ceramic, and has advantages in thermal, chemical, optical and electrical aspects. The type of glass ceramic in the present invention is not limited.

The silicon substrate is a substrate prepared with silicon as a main material. In some embodiments, the silicon substrate may be a silicon wafer substrate or a silicon chip substrate. A silicon wafer is a base material for manufacturing semiconductor elements. The silicon wafer is usually prepared from a high-purity silicon material and is sheet-like. The silicon wafer can be processed into silicon chips through steps such as cutting, grinding, polishing, cleaning.

Generally, the glass substrate, glass ceramic substrate, and silicon substrate are sheet-like and have two main surfaces. According to some embodiments, the glass substrate, glass ceramic substrate, and silicon substrate have two main surfaces and a plurality of vias (e.g., through glass vias (TGV) or through silicon vias (TSV)). Each via is generally cylindrical (straight cylinder or oblique cylinder). According to some embodiments, the glass substrate, glass ceramic substrate, and silicon substrate of the present invention generally have a thickness of about 0.1 mm to 2 mm, such as 0.1 mm, 0.2 mm, 0.3 mm, 0.5 mm, 0.8 mm, 1.0 mm, 1.2 mm, 1.5 mm, or 2 mm, but is not limited thereto. The size of the through holes of the glass substrate, glass ceramic substrate, and silicon substrate may be adjusted depending on the application. In some embodiments, when the glass substrate, glass ceramic substrate, and silicon substrate are used as a glass intermediate layer (or glass interposer) or a silicon intermediate layer (or silicon interposer), the vias of the glass substrate, glass ceramic substrate, and silicon substrate have a diameter of about 5 μm to 500 μm, such as 5 μm, 10 μm, 20 μm, 30 μm, 40 μm, 50 μm, 60 μm, 70 μm, 80 μm, 90 μm, 100 μm, 200 μm, 300 μm, 400 μm, or 500 μm, and generally have an aspect ratio of about 30:1 to about 1:1, such as 30:1, 25:1, 20:1, 15:1, 10:1, 5:1, 3:1, 2:1 or 1:1, but is not limited thereto. In some embodiments, when the glass substrate, glass ceramic substrate, and silicon substrate are used for connecting with an external power source (such as replacing or assisting an IC carrier), the vias of the glass substrate, glass ceramic substrate, and silicon substrate may have a larger size, e.g., a diameter of 100 μm to 500 μm (such as 100 μm, 200 μm, 300 μm, 400 μm or 500 μm), but are not limited thereto.

When a glass substrate, glass ceramic substrate, or silicon substrate is applied to semiconductor package, metal circuits and build-up materials (organic materials or dielectric materials, such as Ajinomoto Build-up Film (ABF) or polyimide) and the like are often disposed on the surface of the glass substrate, glass ceramic substrate, or silicon substrate. However, in general, the adhesion between the substrate material and metal is not good. A method for improving the adhesion between the substrate and the metal includes carrying out surface treatment on the substrate, such as using an adhesion agent. In some embodiments, except high adhesion to the metal, the preferred adhesion agent needs to have good adhesion to the substrate and the subsequent build-up materials. The present invention provides polyimide materials that can used as an adhesion agent, which will be detailed below.

### Polyimide Materials

The present invention provides a polyimide precursor composition, which may be applied to the surface of a substrate, and heated and cured to form a polyimide layer. The polyimide materials of the present invention may be used as an adhesion agent. In some embodiments, the adhesion agent is also called as a modifier or an adhesion promoting agent.

According to some embodiments of the present invention, the polyimide precursor composition includes an amic acid or amic acid ester oligomer having a structure of formula (I):

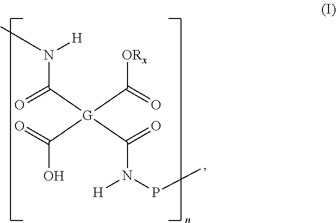

wherein,
each G is independently a tetravalent organic group;
each Rₓ is independently H, C₁-C₁₄ alkyl, or a group containing an ethylenically unsaturated group;
n is an integer from 1 to 200; and
each P is independently a divalent organic group, wherein based on the total mole of all divalent organic groups P in the composition, about 1 mol % to about 20 mol % of the divalent organic groups P are a diamine residue selected from a nitrogen-containing heteroaromatic ring containing at least two nitrogen atoms, an aromatic ring or heterocyclic ring containing at least two —COOH groups, and a combination thereof, and about 0.5 mol % to about 40 mol % of the divalent organic groups P are

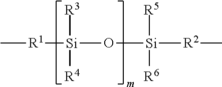

(linear polysiloxane), and the remaining P groups may each independently be other divalent aromatic groups or divalent heterocyclic groups,
wherein,
each of R¹ and R² is independently a C₁-C₄ alkylene group,
each of R³, R⁴, R⁵, and R⁶ is independently H, C₁-C₄ alkyl, or phenyl, and
m is an integer greater than 0.

According to some embodiments of the present invention, about 1 mol % to about 20 mol % of the divalent organic group P is

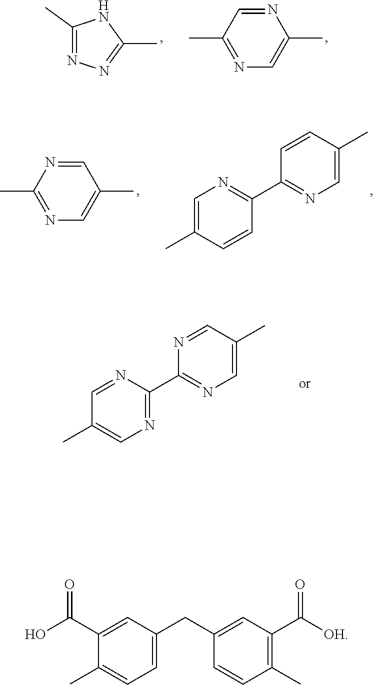

According to some embodiments of the present invention, G is selected from the group consisting of:

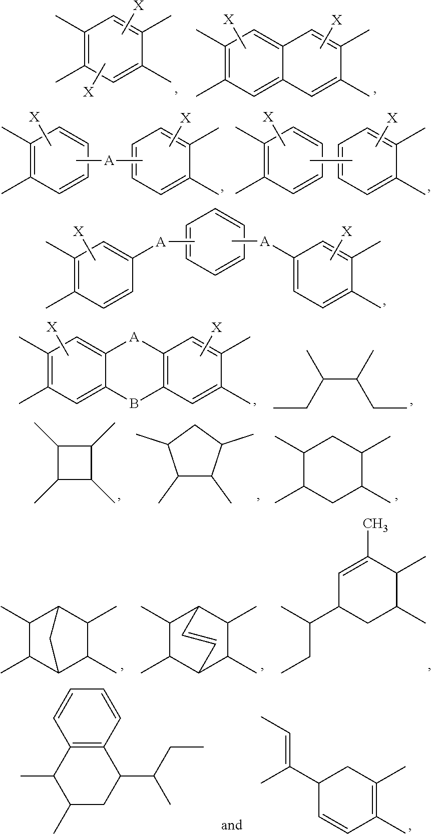

wherein each X is independently H, halogen, C₁-C₄ perfluoroalkyl, or C₁-C₄ alkyl, and each of A and B at each occurrence is independently a covalent bond, a C₁-C₄ alkylene group which is unsubstituted or substituted with one or more groups selected from hydroxyl and C₁-C₄ alkyl, a C₁-C₄ perfluoro-alkylene group, a C₁-C₄ oxyalkylene group, a silanylene group, —O—, —S—, —C(O)—, —OC(O)—, —S(O)₂—, —C(═O)O—(C₁-C₄ alkylene group)-OC(═O)—, —CONH—, a phenylene group, a diphenylene group or

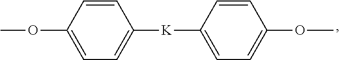

wherein K is —O—, —S(O)₂—, a C₁-C₄ alkylene group, or a C₁-C₄ perfluoro-alkylene group.

According to a preferred embodiment of the present invention, G is selected from the group consisting of:

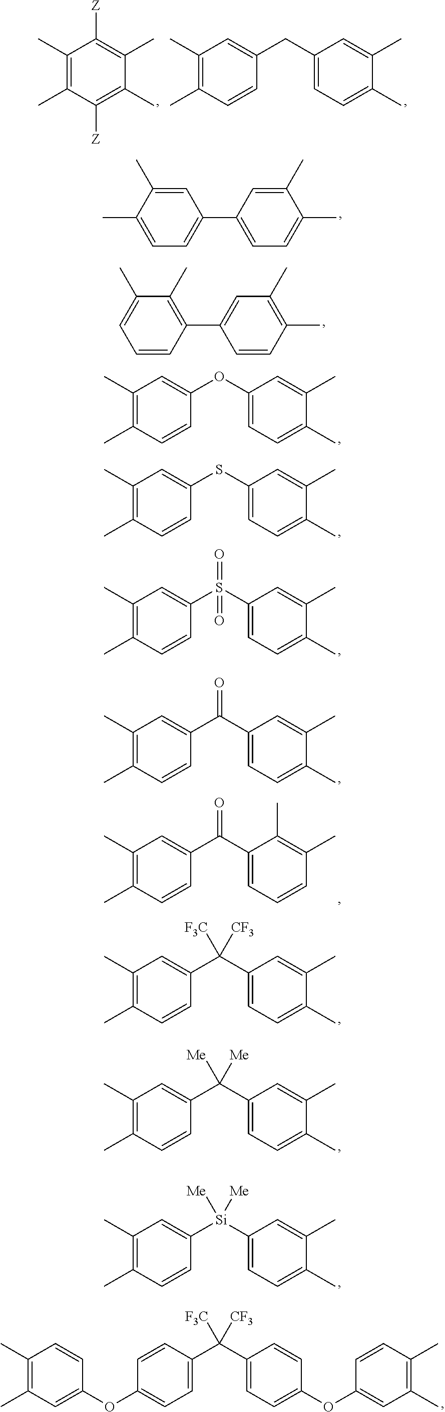

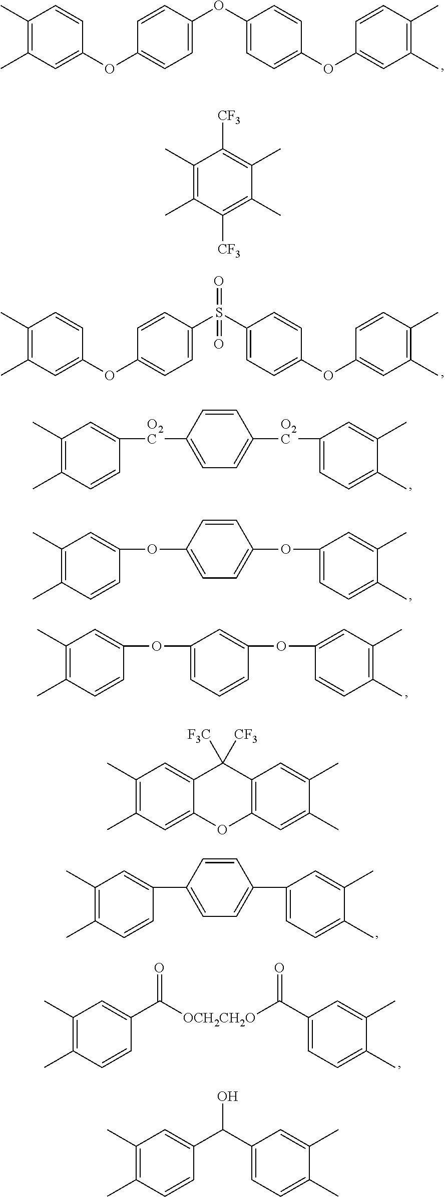

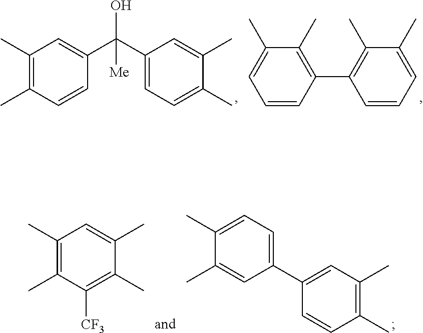

where each Z is independently H, methyl, trifluoromethyl, or halogen.

In order to achieve better adhesion to a substrate (such as a glass substrate, glass ceramic substrate, or silicon substrate) and metal, according to a preferred embodiment of the present invention, G is selected from the group consisting of:

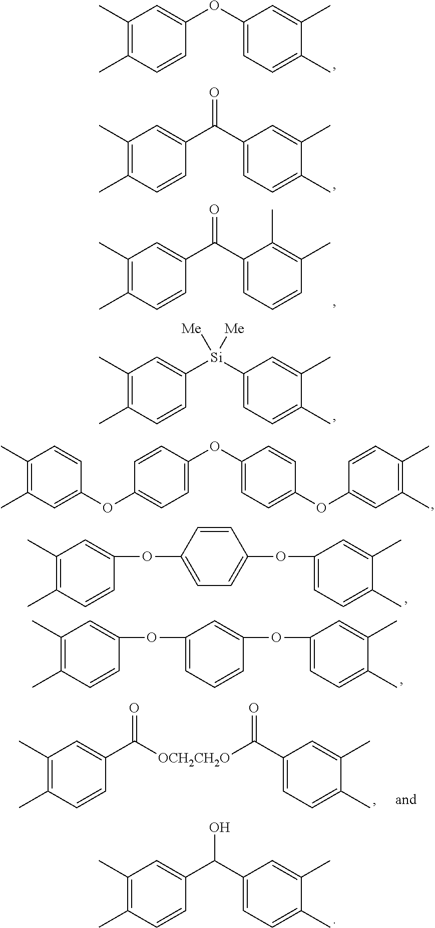

According to some embodiments of the present invention, each Rₓ is independently H, methyl, ethyl, n-propyl, isopropyl, n-butyl, isobutyl, tert-butyl, a 2-hydroxypropyl methylacrylate group, an ethyl methacrylate group, an ethyl acrylate group, an acrylic group, a methacrylate group, n-butenyl, isobutenyl, or selected from the group consisting of:

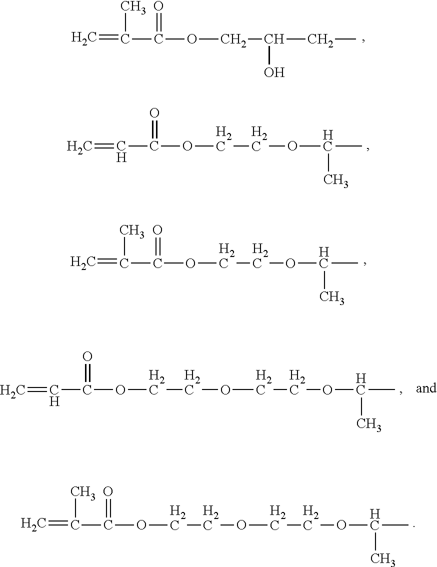

According to some embodiments of the present invention, each Rₓ is independently H, isopropyl, or n-butyl.

According to some embodiments of the present invention, n is 1, 2, 3, 4, 5, 6, 7, 8, 9, 10, 15, 20, 25, 30, 40, 50, 60, 70, 80, 90, 100, 120, 150, 180, or 200, preferably an integer from 5 to 150, more preferably an integer from 9 to 100.

According to some embodiments of the present invention, based on the total mole of all divalent organic groups P in the composition, about 1 mol % to about 20 mol % (such as 1 mol %, 2 mol %, 3 mol %, 4 mol %, 5 mol %, 6 mol %, 7 mol %, 8 mol %, 9 mol %, 10 mol %, 12 mol %, 15 mol %, 16 mol %, 18 mol %, or 20 mol %, preferably 2 mol % to 16 mol %, and more preferably 5 mol % to 12 mol %) of the divalent organic groups P are

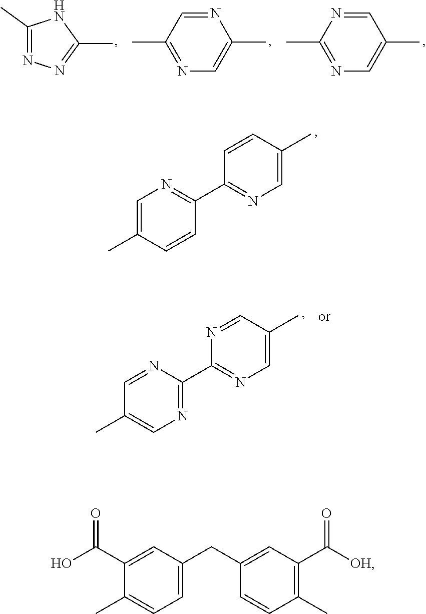

and about 0.5 mol % to about 40 mol % (such as 0.5 mol %, 1 mol %, 2 mol %, 3 mol %, 4 mol %, 5 mol %, 6 mol %, 7 mol %, 8 mol %, 9 mol %, 10 mol %, 12 mol %, 15 mol %, 18 mol %, 20 mol %, 25 mol %, 30 mol %, 35 mol %, or 40 mol %, preferably 5 mol % to 35 mol %, and more preferably 10 mol % to 30 mol %) of the divalent organic groups P are

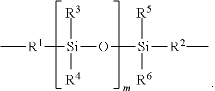

According to some embodiments of the present invention, the remaining P groups may each independently be other divalent aromatic groups or divalent heterocyclic groups, which, for example, may be preferably selected from the group consisting of:

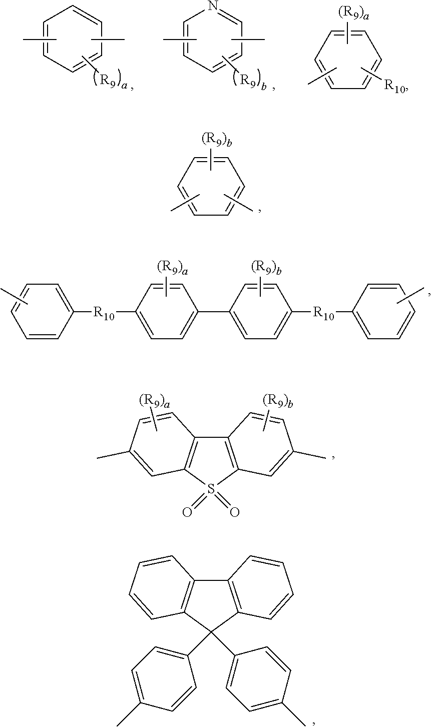

and a combination thereof,
where, each R₉ is independently H, C₁-C₄ alkyl, C₁-C₄ perfluoroalkyl, C₁-C₄ alkoxy, halogen, —OH, —COOH, —NH₂, or —SH; each a is independently an integer from 0 to 4; each b is independently an integer from 0 to 4; R₁₀ is a covalent bond or a group selected from the group consisting of: —O—, —S—, —CH₂—, —S(O)₂—,

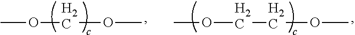

—C(CF₃)₂—, —C(O)—, —C(CH₃)₂—, —CONH—,

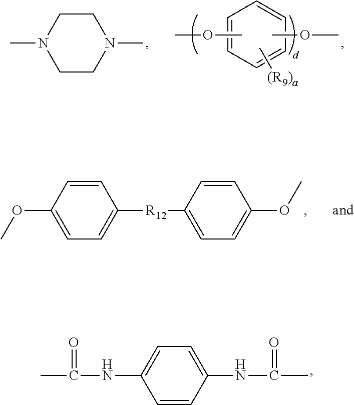

wherein each of c and d is independently an integer from 0 to 20; R₉ and a are as described above, and R₁₂ is —S(O)₂—, a covalent bond, a C₁-C₄ alkylene group, or a C₁-C₄ perfluoro-alkylene group;
said other divalent aromatic groups or divalent heterocyclic groups may be preferably selected from group of:

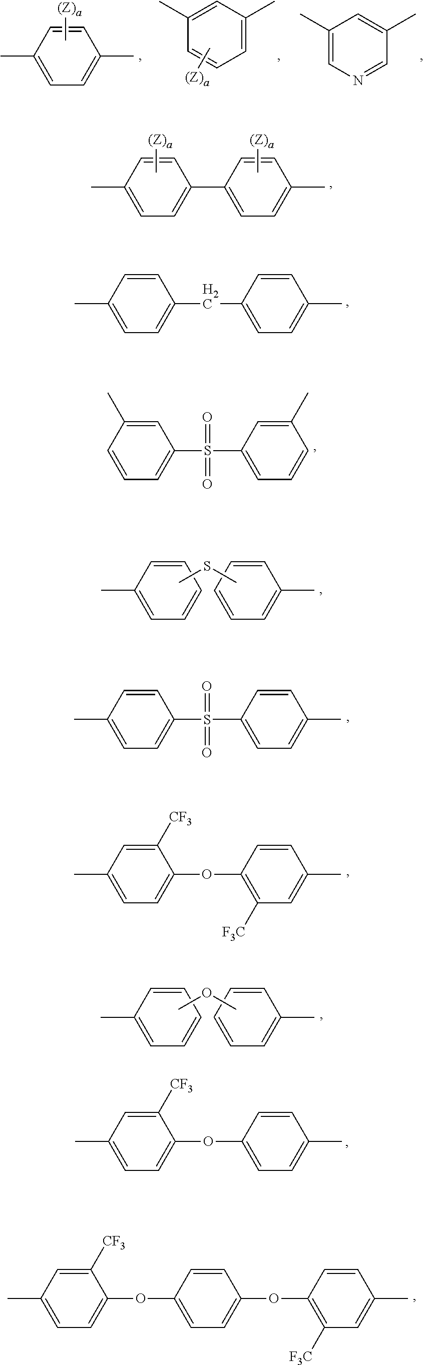

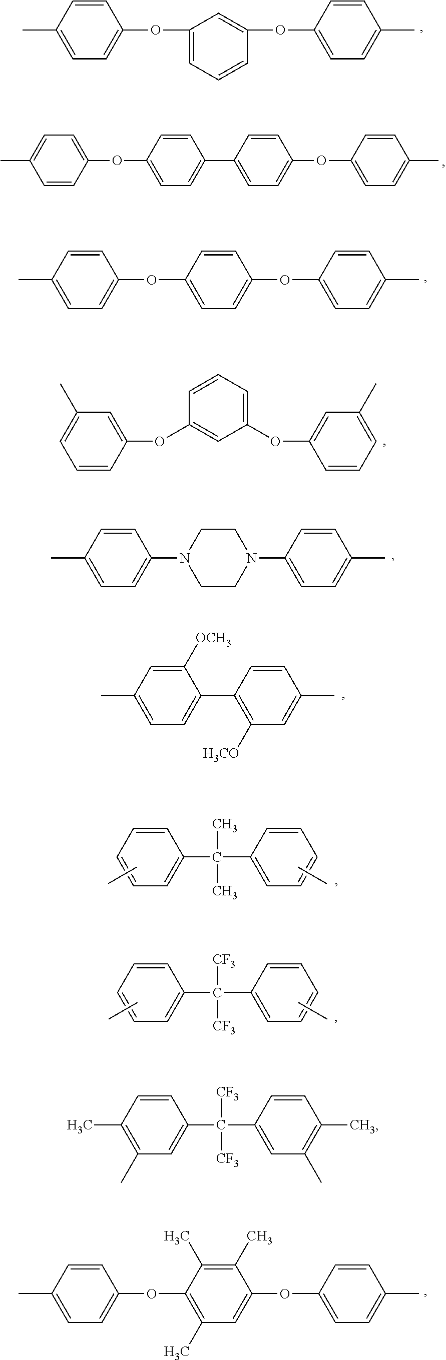

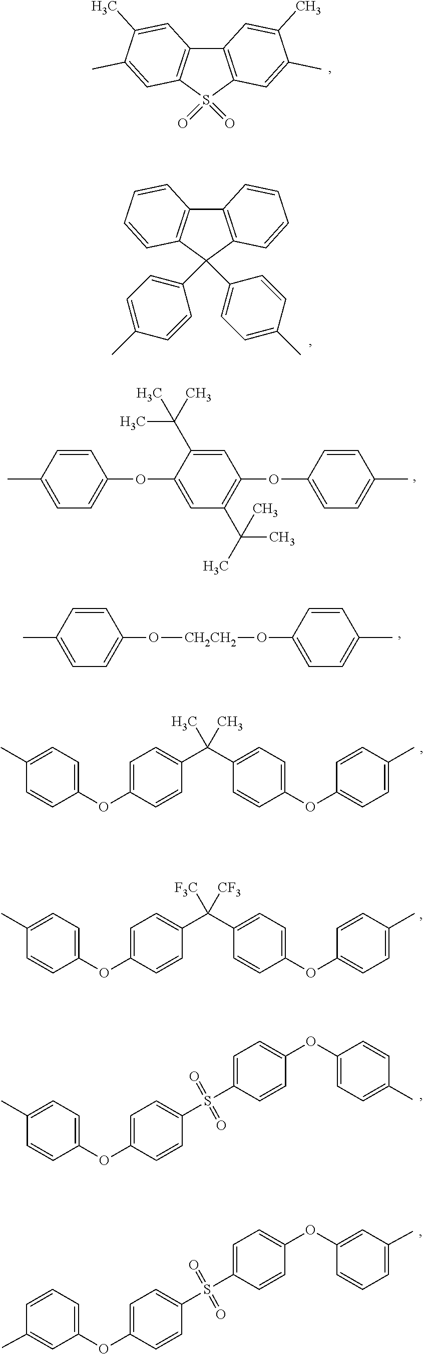

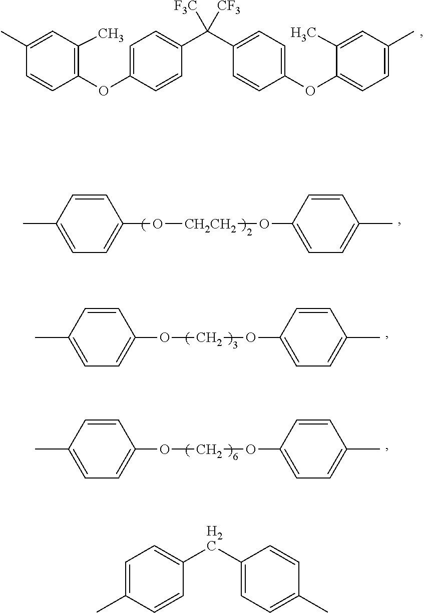

a combination thereof,
wherein each a is independently an integer from 0 to 4, and each Z is independently H, methyl, trifluoromethyl, or halogen;
said other divalent aromatic groups or divalent heterocyclic groups may be most preferably selected from the group consisting of:

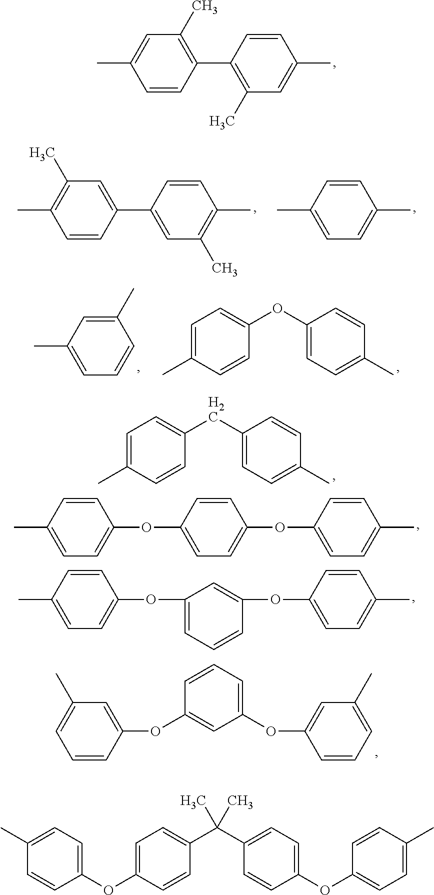

and a combination thereof.

Regarding the formula

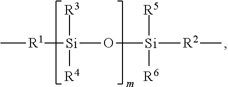

according to some embodiments of the present invention, each of R¹ and R² is independently a methylene group, an ethylene group, an n-propylene group, an isopropylene group, an n-butylene group, an isobutylene group, or a tert-butylene group. According to a preferred embodiment of the present invention, each of R¹ and R² is a methylene group, an ethylene group, or an n-propylene group. According to a more preferred embodiment of the present invention, each of R¹ and R² is an n-propylene group.

According to some embodiments of the present invention, each of R³, R⁴, R⁵, and R⁶ is independently H, methyl, ethyl, n-propyl, isopropyl, n-butyl, isobutyl, tert-butyl, or phenyl. According to some preferred embodiments of the present invention, each of R³, R⁴, R⁵, and R⁶ is methyl.

According to some embodiments of the present invention, m is an integer greater than 0, such as 1, 2, 3, 4, 5, 6, 7, 8, 9, 10, 12, 15, 18, 20, 30, 40, 50, or 100. According to a preferred embodiment of the present invention, m is 1 or 2. According to a more preferred embodiment of the present invention, m is 1.

According to some embodiments of the present invention, the polyimide layer has a repeating unit having a structure of formula (II):

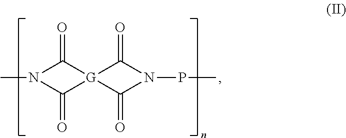

wherein G, P, and n are defined as above.

The polyimide of the present invention is not a block copolymer, but a random copolymer, namely, the divalent organic groups P are distributed randomly within the polyimide, thus simplifying the polymerization process.

Generally, polyimide does not have good adhesion to glass and metal, and if polyimide exhibits adhesion to only one of them, it is still insufficient to achieve the purpose of glass metallization. However, the inventors of the present invention conducted experimental research to provide polyimide materials that show excellent adhesion to both glass and metal. The polyimide materials of the present invention are suitable as an adhesion agent for glass metallization and are applicable to various glass substrates. In addition, the inventors of the present invention also found that the polyimide material of the present invention has excellent adhesion to the glass ceramic substrate, silicon substrate, and metal, so that the polyimide material is also suitable for metallization of the glass ceramic substrate and the silicon substrate. Without being bound by theory, it is believed that this may be due to the specific divalent organic groups P in the polyimide materials. For example, the nitrogen-containing heteroaromatic ring containing at least two nitrogen atoms or the carboxyl (—COOH) in the divalent organic group P has an affinity for metal ions, and through the lone pair electrons on the nitrogen atoms and carboxylate (—COO—), it can act as an electron donor to attract electron-deficient metal ions. In addition, the linear polysiloxane contained in the divalent organic groups P has an affinity for glass, glass ceramic, or silicon, which is due to the structural similarity between the polysiloxane structure and above material. For example, it can form hydrogen bonds with glass or chemical bonds upon heating.

The polyimide precursor composition of the present invention further includes a solvent which can improve the leveling property of the composition. The solvent may be any suitable solvent known by those skilled in the art, and the content of the solvent is not specially limited as long as it can make the composition easy to coat.

According to some embodiments of the present invention, based on the total weight of the whole polyimide precursor composition, the content of the oligomer having the structure of formula (I) is about 0.1 wt % to about 20 wt %, preferably about 1 wt % to about 5 wt %.

The polyimide precursor composition of the present invention may contain other optional materials known in the formulation technology, such as an antioxidant, a hindered amine light stabilizer, a UV light absorber and stabilizer, a surfactant, an initiator, a catalyst, a flow control agent, a thixotropic agent, a filler, an antimold agent, and other conventional aids. The polyimide precursor composition of the present invention has good adhesion to a substrate (such as a glass substrate, glass ceramic substrate, or silicon substrate), metal and dielectric materials without the addition of an adhesion promoting agent.

The polyimide precursor composition of the present invention may be further added with the catalyst as needed to cure the polyimide at a lower curing temperature to achieve the effect of low-temperature curing. According to some embodiments of the present invention, the catalyst of the present invention is amines, such as a tertiary amine, a nitrogen-containing heterocyclic ring or nitrogen-containing heteroaryl. Specific embodiments include triethylamine,

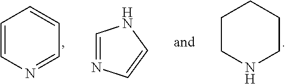

The present invention further provides polyimide prepared from the polyimide precursor composition. The polyimide of the present invention can be obtained by wet coating the polyimide precursor composition on glass or other substrates and heating and cyclizing the polyimide precursor composition. The wet coating may be carried out by any known method in the art, such as dipping/dip-coating, spray coating, spin coating, flow coating, and the like. The polyimide of the present invention is thermosetting polyimide.

The polyimide precursor (oligomer having the structure of formula (I)) of the present invention has low viscosity and good operability due to low molecular weight. The viscosity of the polyimide precursor composition of the present invention may reach only 1 cp to 10 cp (such as 5 cp), and the polyimide precursor composition may permeate into the glass through holes or silicon through holes by capillary phenomenon to form a thin layer, and then be cured to form the polyimide layer. That is, the polyimide layer may be disposed on the walls of a plurality of through holes.

According to some embodiments of the present invention, the curing temperature of the polyimide precursor is 150° C. to 350° C., such as 150° C., 160° C., 170° C., 180° C., 190° C., 200° C., 210° C., 220° C., 230° C., 240° C., 250° C., 300° C., or 350° C. In some preferred embodiments, the polyimide precursor may be cured at a temperature between 150° C. and 250° C. to achieve the purpose of low-temperature curing. According to some embodiments of the present invention, the curing time of the polyimide precursor is 15 min to 200 min, such as 15 min, 30 min, 60 min, 90 min, 120 min, 150 min, 180 min, or 200 min. The heating step of the present invention may be carried out in a single stage, two stages, or multiple stages. For example, heating may be carried out in a first stage at a lower temperature (such as 80° C. or 90° C.) for a short duration (such as 5 min or 10 min) to remove the solvent, and then curing is carried out in a second stage at a higher temperature (such as 150° C.) for a long duration (such as 1 h). If necessary, curing may be carried out in a third stage at a much higher temperature (such as 250° C. or 350° C.) for a longer duration (such as 2 h).

According to some embodiments of the present invention, the polyimide film formed by the polyimide precursor after curing has a thickness of about 0.05 μm to about 20 μm, preferably about 0.1 μm to about 10 μm, such as 0.1 μm, 0.2 μm, 0.3 μm, 0.5 μm, 1 μm, 1.5 μm, 2 μm, 5 μm, or 10 μm.

According to some embodiments of the present invention, the polyimide of the present invention has a glass transition temperature (T_{g}) of about 150° C. to 300° C., such as 150° C., 160° C., 170° C., 180° C., 190° C., 200° C., 210° C., 220° C., 230° C., 240° C., 250° C., 260° C., 270° C., 280° C., 290° C., or 300° C. Conventional polyimide has a T_{g} of 300° C. or more, while the polyimide of the present invention has a lower T_{g} than the conventional polyimide. Therefore, if there is a heating step in the subsequent process and the temperature exceeds the T_{g} of the polyimide of the present invention, the flowability of the polyimide can be improved, which facilitates a tighter alignment/contact between the polyimide and its adjacent layer.

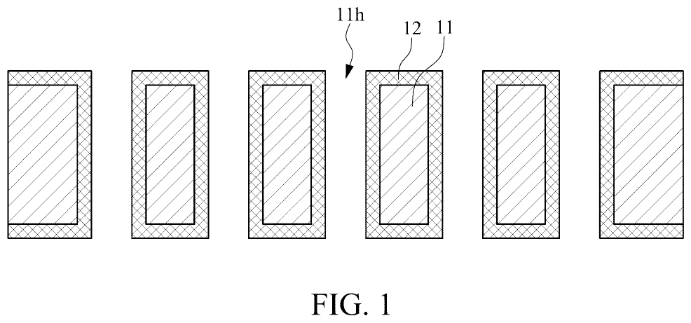

According to a preferred embodiment of the modified substrate the present invention, the substrate has two main surfaces and a plurality of through holes, and the polyimide layer is disposed on at least one main surface and the wall of each through hole of the substrate. FIG. 1 shows a modified substrate according to an embodiment of the present invention. As shown in FIG. 1, the substrate 11 has two main surfaces and a plurality of through holes 11h. The polyimide layer 12 is disposed on each main surface and the wall of each through hole of the substrate 11.

### Metallization Process

Since polyimide is an insulator, a metal layer or a metal circuit cannot be directly manufactured on the surface thereof. It is known in the industry to metallize the polyimide by making the surface of the polyimide conductive using sputtering or electroless plating (which may also be described as forming a tie coating layer or a seed layer on the surface, and the thickness thereof is generally only several nanometers to dozens of nanometers) and then carrying out electroplating. For a method for making the surface of the polyimide conductive by electroless plating, the method specifically includes cleaning and coarsening the surface of a polyimide layer with a cleaning agent, and then activating the surface of the polyimide layer by a surfactant with metal ions, or cleaning and activating the surface of the polyimide layer by a composition containing a cleaning agent and a surfactant; then, reducing the metal ions attached to the surface of a polyimide substrate to a metal catalyst with a reducing agent; and finally, performing electroless plating and/or electroplating on the surface of the polyimide to prepare a metal layer.

The cleaning agent may be an alkaline compound, such as (but not limited to) potassium hydroxide, sodium hydroxide, calcium hydroxide or lithium hydroxide, and preferably includes at least one of potassium hydroxide, sodium hydroxide, calcium hydroxide and lithium hydroxide. The surfactant with metal ions may be (but is not limited to) sulfate, nitrite, diamine nitrite, chloride salt or dichlorodiamine salt of the metal ions, and the metal ions may be (but are not limited to) palladium ions, nickel ions, chromium ions, titanium ions or copper ions, and preferably contain at least one of palladium ions, nickel ions, chromium ions, titanium ions and copper ions. The reducing agent may be (but is not limited to) borohydride (such as sodium borohydride or potassium borohydride), amidoborane (such as diamido borane, trimethylamine borane or triethylamine borane), hydrazine hydrate, hypophosphorous acid or salts thereof (such as sodium hypophosphite or potassium hypophosphite).

In the present invention, the metal circuit may be manufactured by any known suitable metallization process. According to some embodiments of the present invention, a layer of nickel is plated on the surface of the polyimide by electroless plating to serve as a seed layer, and then a layer of copper is plated on the surface of the nickel by electroplating. The polyimide of the present invention has good adhesion to the metal without the need of an adhesion promoting agent as an additive, and without the need of being heated/baked after the metal is plated on the surface of the polyimide. According to some embodiments of the present invention, the peel strength of the polyimide and the metal layer may reach 400 gf/cm or more, such as 400 gf/cm, 500 gf/cm, 600 gf/cm, 700 gf/cm, 800 gf/cm, 900 gf/cm, 1,000 gf/cm, 1,100 gf/cm, 1,200 gf/cm, 1,300 gf/cm, 1,400 gf/cm, or 1,500 gf/cm, preferably 600 gf/cm or more.

According to some embodiments of the present invention, the plated metal layer is filled in through holes of a glass substrate or glass ceramic substrate to form the TGVs or filled in the through holes of the silicon substrate to form the TSVs. The diameter of the TGVs or the TSVs mainly depends on the diameter of the through holes of the glass substrate, glass ceramic substrate, or silicon substrate and the thickness of the polyimide layer disposed on the walls of the through holes.

The plated metal layer is to be patterned to form a desired circuit pattern. An acidic etching solution is generally used in the patterning process. The polyimide of the present invention has acid resistance, so that only the metal layer (and the seed layer) may be etched by the acidic etching solution. In contrast, in the wet metal deposition process in the prior art, the metal oxide is used as an adhesion agent. The metal oxide is also prone to be corroded by the acidic etching solution besides the metal layer, so the stability is poor.

### Application

In some embodiments, the modified substrate of the present invention may be applied to the industries such as micro LEDs, semiconductor packages (such as 2.5D and 3D packages), IC carriers, micro-electro-mechanical systems (MEMS), biochips and 5G chips. Taking the semiconductor packages as an example, the glass or glass ceramic substrate may be used as a glass intermediate layer (or a glass interposer), and the silicon substrate may be used as a silicon intermediate layer (or a silicon interposer).

In some embodiments, redistribution layers (RDL) may be disposed on the upper surface, the lower surface or both the upper and lower surfaces of the substrate to improve the flexibility of IC design and form electric connection for a chip, an IC carrier and/or a printed circuit board (PCB). The RDL includes a patterned metal layer (circuit layer) and an organic insulating layer (dielectric layer). In some embodiments, the organic insulating layer may be a build-up material, which is an organic dielectric material and is used for protecting metal wires, providing an insulating property, reducing dielectric loss and regulating thermal stress-induced warpage. At present, the organic insulating layer material adopted in the industry is an Ajinomoto Build-up Film (ABF) or polyimide. The polyimide of the present invention at least has the following technical feature: the polyimide exposed after the metal layer is patterned has good adhesion when being in direct contact with the subsequently disposed organic insulating layer, because the polyimide and the material of the organic insulating layer are both organic resin and are high in compatibility. In contrast, the wet metal deposition process in the prior art uses a metal oxide as an adhesion agent, which has poor adhesion to the organic insulating layer material, resulting in the risk of easy separation.

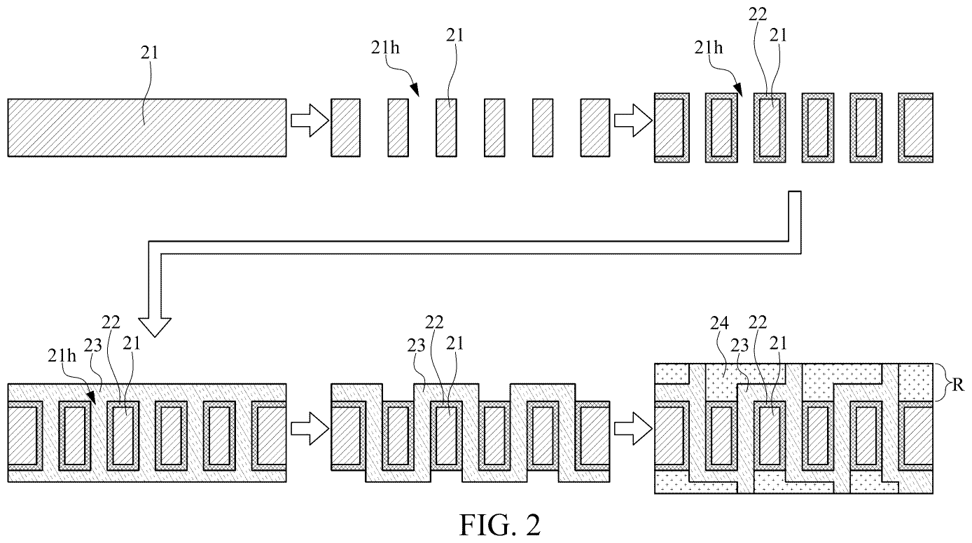

FIG. 2 shows a substrate modification method and a metallization process according to an embodiment of the present invention. As shown in FIG. 2, a substrate 21 was provided. A plurality of through holes 21h penetrating through the upper and lower surfaces of the substrate 21 were formed by etching, laser processing or a combination thereof. Then, a polyimide precursor composition was applied to the upper and lower surfaces of the substrate 21 and the walls of the through holes, followed by heat curing to form a polyimide layer 22. Subsequently, a seed layer (not shown in the figure) was formed on the surface of the polyimide layer 22 by sputtering, electroless plating, etc., and a conductive material (usually copper) was applied to form a conductive layer 23 which filled the through holes 21h to form vias. Then, the conductive layer 23 was patterned to form a metal circuit and expose a portion of the polyimide layer 22. Then, an organic insulating layer 24 was applied and patterned (or planarized) to form a redistribution layer R. The steps may be repeated several times to make the redistribution layer contain more patterned conductive layers 23 and organic insulating layers 24.

In addition, in some embodiments of the present invention, since the polyimide of the present invention has relatively low T_{g}, when there is a heating step in subsequent process and the heating temperature exceeds the T_{g} of the polyimide of the present invention, the flowability of the polyimide can be enhanced, which facilitates a tighter alignment/contact between the polyimide and the organic insulating layer.

The modified substrate of the present invention can be used not only in applications requiring fine metal wiring, such as a glass intermediate layer (or glass interposer) or silicon intermediate layer (or silicon interposer), but is also suitable in the applications with lower requirements for metal wiring fineness, such as IC carrier. The materials of the IC carrier usually include bismaleimide triazine (BT) resin as a core layer, an Ajinomoto Build-up Film (ABF) as a build-up material and metal wires. The IC carrier is electrically connected to an external metal ball with a larger size. The modified substrate of the present invention can replace the bismaleimide triazine (BT) resin as the core layer of the IC carrier, serving as a more advanced alternative and exhibiting comprehensive effects of stability, low transmission loss and the like.

### Modified Substrate

In summary, the modified substrate of the present invention includes the substrate selected from the group consisting of a glass substrate, glass ceramic substrate, and silicon substrate; the polyimide layer disposed on at least one surface of the substrate; and the conductive material disposed on the polyimide layer. The conductive material may be a patterned conductive material. The modified substrate may further includes an organic insulating layer, and a redistribution layer formed by the patterned conductive material and the organic insulating layer.

According to some embodiments, the substrate of the present invention is a glass substrate, and the substrate has a plurality of through holes. According to some embodiments, the polyimide layer is further disposed on the walls of the plurality of through holes.

According to some embodiments, the peel strength between the polyimide layer of the present invention and a substrate (such as a glass substrate, glass ceramic substrate, or silicon substrate) may reach 550 gf/cm or more, and the peel strength between the polyimide layer and a conductive material layer may reach 400 gf/cm or more.

### Examples

The following examples are provided to further illustrate the present invention and are not intended to limit the scope of the present invention. Any modifications and changes that can be easily achieved by those skilled in the art are included within the scope of the disclosure of the specification and the claims attached hereto.

The abbreviations mentioned in the following examples are defined as follows:

### <Dianhydride>

A-1: 3,3′,4,4′-biphenyltetracarboxylic dianhydride;
A-2: 1,2,4,5-benzenetetracarboxylic anhydride;
A-3: 4,4′-(hexafluoroisopropylidene)diphthalic anhydride;
A-4: 4,4′-oxydiphthalic anhydride;
A-5: 3,3′,4,4′-benzophenonetetracarboxylic dianhydride;

### <Diamine>

### <Diamine Having Other Aromatic Groups or Heterocyclic Groups>

D-1: p-phenylenediamine;
D-2: 4,4′-diamino-2,2′-dimethylbiphenyl;
D-3: 4,4′-diaminodiphenyl ether;
D-4: 4,4′-diamino-2,2′-bis(trifluoromethyl)biphenyl;
D-5: 1,3-bis(4-aminophenoxy)benzene;
D-6: 1,4-bis(4-aminophenoxy)benzene;
D-7: 1,3-bis(3-aminophenoxy)benzene;
D-8: 2,2-bis[4-(4-aminophenoxy)phenyl]propane;

### <Diamine Having Linear Polysiloxane and Comparative Diamine Having Analogue Linear Structure>

D-9: 1,3-bis(3-aminopropyl)tetramethyldisiloxane;
D-10: poly(dimethylsiloxane), bis(3-aminopropyl) terminated, Mn: about 2500;
D-11: poly(dimethylsiloxane), bis(3-aminopropyl) terminated, Mn: about 27000;
D-12: poly(ethylene glycol), bis(3-aminopropyl) terminated, Mn: about 1500;
D-13: 4,7,10-trioxa-1,13-tridecanediamine;

### <Diamine Having a Nitrogen-Containing Heteroaromatic Ring or at Least Two —COOH Groups>

D-14: 5,5′-methylenebis(2-aminobenzoic acid);
D-15: [2,2′-bipyridine]-5,5′-diamine;
D-16: [2,2′-bipyrimidine]-5,5′-diamine;
D-17: 3,5-diamino-1,2,4-triazole;

### <Catalyst>

C-1: triethylamine;
C-2: pyridine;
C-3: imidazole;
C-4: piperidine; and
C-5: monoethanolamine.

### <<Preparation of Amic Acid/Amic Acid Ester Oligomer>>

Examples 1-44 and Comparative Examples 1-28: Dianhydride was weighed according to the amounts shown in Tables 1-3, and then poured into a reactor, and 2000 g of NMP solvent was added and stirred. Diamine monomers were added at room temperature and stirred for 1 h, and then, the temperature was increased to 50° C. for heating for 8 h. Then the temperature was decreased to room temperature for collecting. A solvent was added as needed. It was adjusted to obtain an amic acid/amic acid ester oligomer glue solution with a solid content of 20 wt %.

Examples 45-57: The amic acid/amic acid ester oligomer was synthesized in the same method as described above. However, after the temperature was decreased to room temperature, a catalyst with a specified weight percentage (relative to the weight of the amic acid/amic acid ester oligomer) was added, and stirred for 2 h and then collected. Due to the addition of the catalyst, the subsequent curing temperature (see the hard baking temperature in Table 4) was decreased.

Examples 58-66: Compared with Examples 45-57, no catalyst was added, but the lower subsequent curing temperature was still maintained as the same as that in Examples 45-57.

### Test of Peel Strength (Adhesion) Between Polyimide and Glass

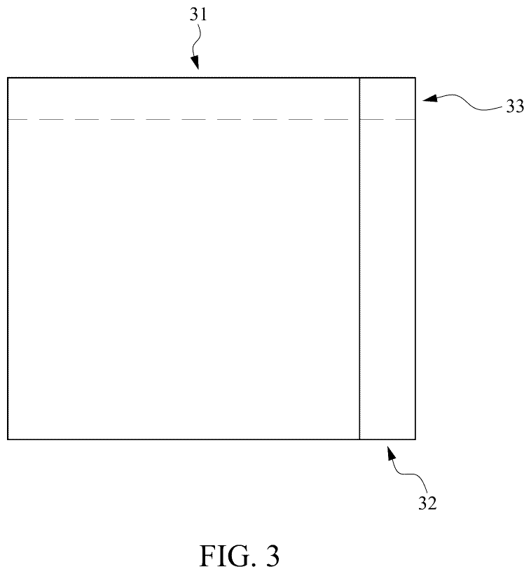

As shown in the schematic diagram in FIG. 3, a glass substrate 31 which was 20 cm×20 cm Corning EXG (thickness of 0.7 mm) was used. A 20 cm×1.5 cm PI adhesive tape 32 was attached to the right side of the upper surface of the glass substrate 31. The glass substrate 31 and the PI adhesive tape 32 were coated with the amic acid/amic acid ester oligomer glue solution of the examples and the comparative examples by spin coating. Then soft baking (90° C./10 min) and hard baking (two stages: 150° C./1 hr+350° C./2 hr or 150° C./1 hr+250° C./2 hr) (depending on different examples) were carried out to prepare a polyimide film with a thickness of 10 μm. The sample subjected to hard baking was cut into 20 cm×1 cm test strips by a blade along a cutting line 33. The PI adhesive tape surfaces of the test strips were separated from glass. The polyimide film on the PI adhesive tape surfaces was pulled up. The tensile strength of the pulled polyimide film was tested by an Instron 3342 tensile machine and recorded. If the peel strength is greater than 550 gf/cm, the polyimide film passes the test. If the polyimide film fails the test, the test of subsequent peel strength (adhesion) between polyimide and metal is not carried out.

### Test of Peel Strength (Adhesion) Between Polyimide and Metal

The amic acid/amic acid ester oligomer glue solution of the examples and the comparative examples were coated on a glass substrate which was 20 cm×20 cm Corning EXG (thickness of 0.7 mm) by spin coating. The PI coating thickness was 1 μm. The soft baking was carried out under 80° C./5 min. Then hard baking was carried out at the temperature of 150° C./1 hr+350° C./2 hr or 150° C./1 hr+250° C./2 hr (according to different samples). After hard baking, the treated sample was soaked in an aqueous solution containing 1.5 g/L sodium hydroxide and 0.5 g/L palladium sulfate at the temperature of 50° C. for 10 min, washed with pure water, then soaked in a 1 M DiaminoBorane_{(aq)} (NH₂—BH—NH₂) aqueous solution at the temperature of 25° C. for 10 min, then washed with pure water, and dried. Electroless nickel plating was carried out (NPR-18 (prepared by C. Uyemura & Co., Ltd.), 45° C., 3 min), and copper was electroplated to reach a thickness of 18 μm (the electroplating solution includes 70 g/L copper sulfate, 200 g/L sulfuric acid, 50 mg/L chloride ions, and 5 mL/L electroplating additive (LUCINA SF-M, OKUNO Chemical Industries Co., Ltd.); electroplating temperature: 25° C.; cathode current density: 3 A/dm²).

The sample was cut into 20 cm×1 cm test strips. The polyimide layers were slightly separated from the copper plated layer at the end of the test strips. The peel strength was tested by an Instron 3342 tensile machine. The peel strength greater than 400 gf/cm is considered passed.

The hard baking temperature in the second stage and the test result of each example and comparative example are recorded in Table 1 to Table 4.

TABLE 1

| | | | | | | | | Peel strength | Peel strength |
|---|---|---|---|---|---|---|---|---|---|
| | | | | | | | | between | between |
| | | | | | | | Hard baking | polyimide and | polyimide and |
| | | Dianhydride | Diamine | | | Catalyst | temperature | glass (gf/cm) | metal (gf/cm) |
| Example 1 | Monomer | A-1 | D-1 | D-9 | D-17 | — | 350° C. | 1079 | 579 |
| | Amount (mol ratio) | 1 | 0.895 | 0.005 | 0.1 | — | | | |
| Example 2 | Monomer | A-1 | D-1 | D-9 | D-17 | — | 350° C. | 1318 | 689 |
| | Amount (mol ratio) | 1 | 0.89 | 0.01 | 0.1 | — | | | |
| Example 3 | Monomer | A-1 | D-1 | D-9 | D-17 | — | 350° C. | >1600 | 748 |
| | Amount (mol ratio) | 1 | 0.85 | 0.05 | 0.1 | — | | | |
| Example 4 | Monomer | A-1 | D-1 | D-9 | D-17 | — | 350° C. | >1600 | 808 |
| | Amount (mol ratio) | 1 | 0.8 | 0.1 | 0.1 | — | | | |
| Example 5 | Monomer | A-1 | D-1 | D-9 | D-17 | — | 350° C. | >1600 | 846 |
| | Amount (mol ratio) | 1 | 0.75 | 0.15 | 0.1 | — | | | |
| Example 6 | Monomer | A-1 | D-6 | D-9 | D-17 | — | 350° C. | >1600 | 873 |
| | Amount (mol ratio) | 1 | 0.7 | 0.2 | 0.1 | — | | | |
| Example 7 | Monomer | A-1 | D-7 | D-9 | D-17 | — | 350° C. | >1600 | 889 |
| | Amount (mol ratio) | 1 | 0.6 | 0.3 | 0.1 | — | | | |
| Example 8 | Monomer | A-1 | D-8 | D-9 | D-17 | — | 350° C. | >1600 | 895 |
| | Amount (mol ratio) | 1 | 0.5 | 0.4 | 0.1 | — | | | |
| Comparative | Monomer | A-1 | D-1 | — | — | — | 350° C. | 0 | NA |
| Example | Amount (mol ratio) | 1 | 1 | — | — | — | | | |
| 1 | | | | | | | | | |
| Comparative | Monomer | A-1 | D-1 | D-9 | — | — | 350° C. | 137 | NA |
| Example | Amount (mol ratio) | 1 | 0.999 | 0.001 | — | — | | | |
| 2 | | | | | | | | | |
| Comparative | Monomer | A-1 | D-1 | D-9 | — | — | 350° C. | 572 | 0 |
| Example | Amount (mol ratio) | 1 | 0.9975 | 0.0025 | — | — | | | |
| 3 | | | | | | | | | |
| Comparative | Monomer | A-1 | D-1 | D-9 | — | — | 350° C. | 978 | 0 |
| Example | Amount (mol ratio) | 1 | 0.995 | 0.005 | — | — | | | |
| 4 | | | | | | | | | |
| Comparative | Monomer | A-1 | D-1 | D-9 | — | — | 350° C. | 1569 | 0 |
| Example | Amount (mol ratio) | 1 | 0.99 | 0.01 | — | — | | | |
| 5 | | | | | | | | | |
| Comparative | Monomer | A-1 | D-1 | D-9 | — | — | 350° C. | >1600 | 107 |
| Example | Amount (mol ratio) | 1 | 0.95 | 0.05 | — | — | | | |
| 6 | | | | | | | | | |
| Comparative | Monomer | A-1 | D-1 | D-9 | — | — | 350° C. | >1600 | 178 |
| Example | Amount (mol ratio) | 1 | 0.9 | 0.1 | — | — | | | |
| 7 | | | | | | | | | |
| Comparative | Monomer | A-1 | D-1 | D-9 | — | — | 350° C. | >1600 | 181 |
| Example | Amount (mol ratio) | 1 | 0.8 | 0.2 | — | — | | | |
| 8 | | | | | | | | | |
| Comparative | Monomer | A-1 | D-1 | D-9 | — | — | 350° C. | >1600 | 175 |
| Example | Amount (mol ratio) | 1 | 0.7 | 0.3 | — | — | | | |
| 9 | | | | | | | | | |
| Comparative | Monomer | A-1 | D-1 | D-9 | — | — | 350° C. | >1600 | 98 |
| Example | Amount (mol ratio) | 1 | 0.6 | 0.4 | — | — | | | |
| 10 | | | | | | | | | |
| Comparative | Monomer | A-1 | D-1 | D-9 | D-17 | — | 350° C. | 0 | NA |
| Example | Amount (mol ratio) | 1 | 0.9 | 0 | 0.1 | — | | | |
| 11 | | | | | | | | | |
| Comparative | Monomer | A-1 | D-1 | D-9 | D-17 | — | 350° C. | 98 | NA |
| Example | Amount (mol ratio) | 1 | 0.899 | 0.001 | 0.1 | — | | | |
| 12 | | | | | | | | | |
| Comparative | Monomer | A-1 | D-1 | D-9 | D-17 | — | 350° C. | 0 | NA |
| Example | Amount (mol ratio) | 1 | 0.95 | 0 | 0.05 | — | | | |
| 13 | | | | | | | | | |
| Comparative | Monomer | A-1 | D-1 | D-9 | D-17 | — | 350° C. | 553 | 47 |
| Example | Amount (mol ratio) | 1 | 0.8975 | 0.0025 | 0.1 | — | | | |
| 14 | | | | | | | | | |
| Comparative | Monomer | A-1 | D-8 | D-9 | D-17 | — | 350° C. | >1600 | 129 |
| Example | Amount (mol ratio) | 1 | 0.4 | 0.5 | 0.1 | — | | | |
| 15 | | | | | | | | | |

TABLE 2

| | | | | | | | | Peel strength | Peel strength |
|---|---|---|---|---|---|---|---|---|---|
| | | | | | | | | between | between |
| | | | | | | | Hard baking | polyimide and | polyimide and |
| | | Dianhydride | Diamine | | | Catalyst | temperature | glass (gf/cm) | metal (gf/cm) |
| Comparative | Monomer | A-1 | D-2 | D-9 | D-17 | — | 350° C. | 675 | 140 |
| Example 16 | Amount (mol ratio) | 1 | 0.8975 | 0.0025 | 0.1 | — | | | |
| Example 9 | Monomer | A-1 | D-2 | D-9 | D-17 | — | 350° C. | 1079 | 579 |
| | Amount (mol ratio) | 1 | 0.895 | 0.005 | 0.1 | — | | | |
| Example 10 | Monomer | A-1 | D-2 | D-9 | D-17 | — | 350° C. | >1600 | 689 |
| | Amount (mol ratio) | 1 | 0.89 | 0.01 | 0.1 | — | | | |
| Example 11 | Monomer | A-1 | D-2 | D-9 | D-17 | — | 350° C. | >1600 | 748 |
| | Amount (mol ratio) | 1 | 0.85 | 0.05 | 0.1 | — | | | |
| Comparative | Monomer | A-1 | D-3 | D-9 | D-17 | — | 350° C. | 973 | 357 |
| Example 17 | Amount (mol ratio) | 1 | 0.8975 | 0.0025 | 0.1 | — | | | |
| Example 12 | Monomer | A-1 | D-3 | D-9 | D-17 | — | 350° C. | >1600 | 634 |
| | Amount (mol ratio) | 1 | 0.895 | 0.005 | 0.1 | — | | | |
| Example 13 | Monomer | A-1 | D-3 | D-9 | D-17 | — | 350° C. | >1600 | 710 |
| | Amount (mol ratio) | 1 | 0.89 | 0.01 | 0.1 | — | | | |
| Example 14 | Monomer | A-1 | D-3 | D-9 | D-17 | — | 350° C. | >1600 | 795 |
| | Amount (mol ratio) | 1 | 0.85 | 0.05 | 0.1 | — | | | |
| Example 15 | Monomer | A-1 | D-3 | D-9 | D-17 | — | 350° C. | >1600 | 834 |
| | Amount (mol ratio) | 1 | 0.8 | 0.1 | 0.1 | — | | | |
| Example 16 | Monomer | A-1 | D-3 | D-9 | D-17 | — | 350° C. | >1600 | 901 |
| | Amount (mol ratio) | 1 | 0.7 | 0.2 | 0.1 | — | | | |
| Example 17 | Monomer | A-1 | D-4 | D-9 | D-17 | — | 350° C. | >1600 | 505 |
| | Amount (mol ratio) | 1 | 0.85 | 0.05 | 0.1 | — | | | |
| Example 18 | Monomer | A-1 | D-5 | D-9 | D-17 | — | 350° C. | >1600 | 784 |
| | Amount (mol ratio) | 1 | 0.85 | 0.05 | 0.1 | — | | | |
| Example 19 | Monomer | A-1 | D-6 | D-9 | D-17 | — | 350° C. | >1600 | 801 |
| | Amount (mol ratio) | 1 | 0.85 | 0.05 | 0.1 | — | | | |
| Example 20 | Monomer | A-1 | D-7 | D-9 | D-17 | — | 350° C. | >1600 | 815 |
| | Amount (mol ratio) | 1 | 0.85 | 0.05 | 0.1 | — | | | |
| Example 21 | Monomer | A-1 | D-8 | D-9 | D-17 | — | 350° C. | >1600 | 727 |
| | Amount (mol ratio) | 1 | 0.85 | 0.05 | 0.1 | — | | | |
| Comparative | Monomer | A-1 | D-3 | D-9 | D-17 | — | 350° C. | >1600 | 325 |
| Example 18 | Amount (mol ratio) | 1 | 0.4 | 0.5 | 0.1 | — | | | |
| Comparative | Monomer | A-1 | D-3 | D-9 | D-17 | — | 350° C. | 207 | NA |
| Example 19 | Amount (mol ratio) | 1 | 0.899 | 0.001 | 0.1 | — | | | |

TABLE 3

| | | | | | | | | Peel strength | Peel strength |
|---|---|---|---|---|---|---|---|---|---|
| | | | | | | | | between | between |
| | | | | | | | Hard baking | polyimide and | polyimide and |
| | | Dianhydride | Diamine | | | Catalyst | temperature | glass (gf/cm) | metal (gf/cm) |
| Comparative | Monomer | A-2 | D-3 | D-9 | D-17 | — | 350° C. | 437 | NA |
| Example 20 | Amount | 1 | 0.8975 | 0.0025 | 0.1 | — | | | |
| | (mol ratio) | | | | | | | | |
| Comparative | Monomer | A-3 | D-3 | D-9 | D-17 | — | 350° C. | 395 | NA |
| Example 21 | Amount | 1 | 0.8975 | 0.0025 | 0.1 | — | | | |
| | (mol ratio) | | | | | | | | |
| Comparative | Monomer | A-4 | D-3 | D-9 | D-17 | — | 350° C. | 371 | NA |
| Example 22 | Amount | 1 | 0.8975 | 0.0025 | 0.1 | — | | | |
| | (mol ratio) | | | | | | | | |
| Comparative | Monomer | A-5 | D-3 | D-9 | D-17 | — | 350° C. | 330 | NA |
| Example 23 | Amount | 1 | 0.8975 | 0.0025 | 0.1 | — | | | |
| | (mol ratio) | | | | | | | | |
| Example 22 | Monomer | A-2 | D-3 | D-9 | D-17 | — | 350° C. | >1600 | 880 |
| | Amount | 1 | 0.88 | 0.02 | 0.1 | — | | | |
| | (mol ratio) | | | | | | | | |
| Example 23 | Monomer | A-3 | D-3 | D-9 | D-17 | — | 350° C. | >1600 | 457 |
| | Amount | 1 | 0.88 | 0.02 | 0.1 | — | | | |
| | (mol ratio) | | | | | | | | |
| Example 24 | Monomer | A-4 | D-3 | D-9 | D-17 | — | 350° C. | >1600 | 873 |
| | Amount | 1 | 0.88 | 0.02 | 0.1 | — | | | |
| | (mol ratio) | | | | | | | | |
| Example 25 | Monomer | A-5 | D-3 | D-9 | D-17 | — | 350° C. | >1600 | 864 |
| | Amount | 1 | 0.88 | 0.02 | 0.1 | — | | | |
| | (mol ratio) | | | | | | | | |
| Example 26 | Monomer | A-5 | D-3 | D-10 | D-17 | — | 350° C. | 983 | 473 |
| | Amount | 1 | 0.85 | 0.05 | 0.1 | — | | | |
| | (mol ratio) | | | | | | | | |
| Example 27 | Monomer | A-5 | D-3 | D-11 | D-17 | — | 350° C. | 568 | 412 |
| | Amount | 1 | 0.85 | 0.05 | 0.1 | — | | | |
| | (mol ratio) | | | | | | | | |
| Comparative | Monomer | A-5 | D-3 | D-12 | D-17 | — | 350° C. | 213 | NA |
| Example 24 | Amount | 1 | 0.89 | 0.01 | 0.1 | — | | | |
| | (mol ratio) | | | | | | | | |
| Comparative | Monomer | A-5 | D-3 | D-13 | D-17 | — | 350° C. | 357 | NA |
| Example 25 | Amount | 1 | 0.85 | 0.05 | 0.1 | — | | | |
| | (mol ratio) | | | | | | | | |
| Comparative | Monomer | A-5 | D-3 | D-14 | D-17 | — | 350° C. | 457 | NA |
| Example 26 | Amount | 1 | 0.8 | 0.1 | 0.1 | — | | | |
| | (mol ratio) | | | | | | | | |
| Example 28 | Monomer | A-5 | D-3 | D-9 | D-14 | — | 350° C. | >1600 | 458 |
| | Amount | 1 | 0.9 | 0.05 | 0.05 | — | | | |
| | (mol ratio) | | | | | | | | |
| Example 29 | Monomer | A-5 | D-3 | D-9 | D-14 | — | 350° C. | >1600 | 677 |
| | Amount | 1 | 0.85 | 0.05 | 0.1 | — | | | |
| | (mol ratio) | | | | | | | | |
| Example 30 | Monomer | A-5 | D-3 | D-9 | D-15 | — | 350° C. | >1600 | 438 |
| | Amount | 1 | 0.9 | 0.05 | 0.05 | — | | | |
| | (mol ratio) | | | | | | | | |
| Example 31 | Monomer | A-5 | D-3 | D-9 | D-15 | — | 350° C. | >1600 | 578 |
| | Amount | 1 | 0.85 | 0.05 | 0.1 | — | | | |
| | (mol ratio) | | | | | | | | |
| Example 32 | Monomer | A-5 | D-3 | D-9 | D-16 | — | 350° C. | >1600 | 593 |
| | Amount | 1 | 0.9 | 0.05 | 0.05 | — | | | |
| | (mol ratio) | | | | | | | | |
| Example 33 | Monomer | A-5 | D-3 | D-9 | D-16 | — | 350° C. | >1600 | 672 |
| | Amount | 1 | 0.85 | 0.05 | 0.1 | — | | | |
| | (mol ratio) | | | | | | | | |
| Example 34 | Monomer | A-5 | D-3 | D-9 | D-17 | — | 350° C. | >1600 | 890 |
| | Amount | 1 | 0.9 | 0.05 | 0.05 | — | | | |
| | (mol ratio) | | | | | | | | |
| Comparative | Monomer | A-5 | D-3 | D-9 | D-17 | — | 350° C. | >1600 | 355 |
| Example 27 | Amount | 1 | 0.9475 | 0.05 | 0.0025 | — | | | |
| | (mol ratio) | | | | | | | | |
| Example 35 | Monomer | A-5 | D-3 | D-9 | D-17 | — | 350° C. | >1600 | 515 |
| | Amount | 1 | 0.945 | 0.05 | 0.005 | — | | | |
| | (mol ratio) | | | | | | | | |
| Example 36 | Monomer | A-5 | D-3 | D-9 | D-17 | — | 350° C. | >1600 | 597 |
| | Amount | 1 | 0.94 | 0.05 | 0.01 | — | | | |
| | (mol ratio) | | | | | | | | |
| Example 37 | Monomer | A-5 | D-3 | D-9 | D-17 | — | 350° C. | >1600 | 957 |
| | Amount | 1 | 0.85 | 0.05 | 0.1 | — | | | |
| | (mol ratio) | | | | | | | | |
| Example 38 | Monomer | A-5 | D-3 | D-9 | D-17 | — | 350° C. | >1600 | 814 |
| | Amount | 1 | 0.75 | 0.05 | 0.2 | — | | | |
| | (mol ratio) | | | | | | | | |
| Comparative | Monomer | A-5 | D-3 | D-9 | D-17 | — | 350° C. | >1600 | 310 |
| Example 28 | Amount | 1 | 0.65 | 0.05 | 0.3 | — | | | |
| | (mol ratio) | | | | | | | | |
| Example 39 | Monomer | A-4 | D-3 | D-9 | D-17 | — | 350° C. | >1600 | 795 |
| | Amount | 1 | 0.94 | 0.05 | 0.01 | — | | | |
| | (mol ratio) | | | | | | | | |
| Example 40 | Monomer | A-4 | D-3 | D-9 | D-17 | — | 350° C. | >1600 | 1015 |
| | Amount | 1 | 0.85 | 0.05 | 0.1 | — | | | |
| | (mol ratio) | | | | | | | | |
| Example 41 | Monomer | A-4 | D-3 | D-9 | D-17 | — | 350° C. | >1600 | 1123 |
| | Amount | 1 | 0.75 | 0.05 | 0.2 | — | | | |
| | (mol ratio) | | | | | | | | |
| Example 42 | Monomer | A-3 | D-3 | D-9 | D-17 | — | 350° C. | >1600 | 547 |
| | Amount | 1 | 0.85 | 0.05 | 0.1 | — | | | |
| | (mol ratio) | | | | | | | | |
| Example 43 | Monomer | A-2 | D-3 | D-9 | D-17 | — | 350° C. | >1600 | 567 |
| | Amount | 1 | 0.85 | 0.05 | 0.1 | — | | | |
| | (mol ratio) | | | | | | | | |
| Example 44 | Monomer | A-1 | D-3 | D-9 | D-17 | — | 350° C. | >1600 | 594 |
| | Amount | 1 | 0.85 | 0.05 | 0.1 | — | | | |
| | (mol ratio) | | | | | | | | |

TABLE 4

| | | | | | | | | Peel | Peel |
|---|---|---|---|---|---|---|---|---|---|
| | | | | | | | | strength | strength |
| | | | | | | | | between | between |
| | | | | | | | | polyimide | polyimide |
| | | | | | | Catalyst | Hard baking | and glass | and metal |
| | | Dianhydride | Diamine | | | (wt %) | temperature | (gf/cm) | (gf/cm) |
| Example 45 | Monomer | A-1 | D-3 | D-9 | D-17 | C-1 | 250° C. | >1600 | 497 |
| | Amount | 1 | 0.85 | 0.05 | 0.1 | 0.5 | | | |
| | (mol ratio) | | | | | wt % | | | |
| Example 46 | Monomer | A-2 | D-3 | D-9 | D-17 | C-1 | 250° C. | >1600 | 503 |
| | Amount | 1 | 0.85 | 0.05 | 0.1 | 0.5 | | | |
| | (mol ratio) | | | | | wt % | | | |
| Example 47 | Monomer | A-3 | D-3 | D-9 | D-17 | C-1 | 250° C. | >1600 | 530 |
| | Amount | 1 | 0.85 | 0.05 | 0.1 | 0.5 | | | |
| | (mol ratio) | | | | | wt % | | | |
| Example 48 | Monomer | A-4 | D-3 | D-9 | D-17 | C-1 | 250° C. | >1600 | 678 |
| | Amount | 1 | 0.85 | 0.05 | 0.1 | 0.5 | | | |
| | (mol ratio) | | | | | wt % | | | |
| Example 49 | Monomer | A-5 | D-3 | D-9 | D-17 | C-1 | 250° C. | >1600 | 669 |
| | Amount | 1 | 0.85 | 0.05 | 0.1 | 0.5 | | | |
| | (mol ratio) | | | | | wt % | | | |
| Example 50 | Monomer | A-5 | D-3 | D-9 | D-17 | C-1 | 250° C. | >1600 | 536 |
| | Amount | 1 | 0.85 | 0.05 | 0.1 | 0.05 | | | |
| | (mol ratio) | | | | | wt % | | | |
| Example 51 | Monomer | A-5 | D-3 | D-9 | D-17 | C-1 | 250° C. | >1600 | 572 |
| | Amount | 1 | 0.85 | 0.05 | 0.1 | 0.1 | | | |
| | (mol ratio) | | | | | wt % | | | |
| Example 52 | Monomer | A-5 | D-3 | D-9 | D-17 | C-1 | 250° C. | >1600 | 519 |
| | Amount | 1 | 0.85 | 0.05 | 0.1 | 0.25 | | | |
| | (mol ratio) | | | | | wt % | | | |
| Example 53 | Monomer | A-5 | D-3 | D-9 | D-17 | C-1 | 250° C. | >1600 | 659 |
| | Amount | 1 | 0.85 | 0.05 | 0.1 | 1 | | | |
| | (mol ratio) | | | | | wt % | | | |
| Example 54 | Monomer | A-5 | D-3 | D-9 | D-17 | C-1 | 250° C. | >1600 | 647 |
| | Amount | 1 | 0.85 | 0.05 | 0.1 | 5 | | | |
| | (mol ratio) | | | | | wt % | | | |
| Example 55 | Monomer | A-5 | D-3 | D-9 | D-17 | C-2 | 250° C. | >1600 | 592 |
| | Amount | 1 | 0.85 | 0.05 | 0.1 | 1 | | | |
| | (mol ratio) | | | | | wt % | | | |
| Example 56 | Monomer | A-5 | D-3 | D-9 | D-17 | C-3 | 250° C. | >1600 | 671 |
| | Amount | 1 | 0.85 | 0.05 | 0.1 | 1 | | | |
| | (mol ratio) | | | | | wt % | | | |
| Example 57 | Monomer | A-5 | D-3 | D-9 | D-17 | C-4 | 250° C. | >1600 | 549 |
| | Amount | 1 | 0.85 | 0.05 | 0.1 | 1 | | | |
| | (mol ratio) | | | | | wt % | | | |
| Example 58 | Monomer | A-5 | D-3 | D-9 | D-17 | — | 250° C. | >1600 | 619 |
| | Amount | 1 | 0.8 | 0.1 | 0.1 | — | | | |
| | (mol ratio) | | | | | | | | |
| Example 59 | Monomer | A-5 | D-3 | D-9 | D-17 | — | 250° C. | >1600 | 687 |
| | Amount | 1 | 0.7 | 0.2 | 0.1 | — | | | |
| | (mol ratio) | | | | | | | | |
| Example 60 | Monomer | A-5 | D-3 | D-9 | D-17 | — | 250° C. | >1600 | 653 |
| | Amount | 1 | 0.6 | 0.3 | 0.1 | — | | | |
| | (mol ratio) | | | | | | | | |
| Example 61 | Monomer | A-4 | D-3 | D-9 | D-17 | — | 250° C. | >1600 | 703 |
| | Amount | 1 | 0.8 | 0.1 | 0.1 | — | | | |
| | (mol ratio) | | | | | | | | |
| Example 62 | Monomer | A-4 | D-3 | D-9 | D-17 | — | 250° C. | >1600 | 798 |
| | Amount | 1 | 0.7 | 0.2 | 0.1 | — | | | |
| | (mol ratio) | | | | | | | | |
| Example 63 | Monomer | A-4 | D-3 | D-9 | D-17 | — | 250° C. | >1600 | 746 |
| | Amount | 1 | 0.6 | 0.3 | 0.1 | — | | | |
| | (mol ratio) | | | | | | | | |
| Example 64 | Monomer | A-1 | D-3 | D-9 | D-17 | — | 250° C. | >1600 | 427 |
| | Amount | 1 | 0.7 | 0.2 | 0.1 | — | | | |
| | (mol ratio) | | | | | | | | |
| Example 65 | Monomer | A-2 | D-3 | D-9 | D-17 | — | 250° C. | >1600 | 405 |
| | Amount | 1 | 0.7 | 0.2 | 0.1 | — | | | |
| | (mol ratio) | | | | | | | | |
| Example 66 | Monomer | A-3 | D-3 | D-9 | D-17 | — | 250° C. | >1600 | 439 |
| | Amount | 1 | 0.7 | 0.2 | 0.1 | — | | | |
| | (mol ratio) | | | | | | | | |

As shown in Tables 1 to 4, the polyimide of the present invention includes the diamine residue selected from the nitrogen-containing heteroaromatic ring containing at least two nitrogen atoms, the aromatic ring or heterocyclic ring containing at least two —COOH groups, and the combination thereof, and the

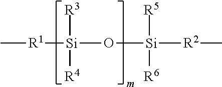

group, so the peel strength between the polyimide and glass can reach 550 gf/cm or more, and the peel strength between the polyimide and metal can reach 400 gf/cm or more.

In addition, the polyimides of Example 58 and Example 61 were selected to test the influence of different glasses on the tensile strength, as shown in Table 5.

TABLE 5

| | | | Peel strength | Peel strength |
|---|---|---|---|---|
| | | | between | between |
| | | | polyimide | polyimide |
| | Model of | Hard baking | and glass | and metal |
| Polyimide | glass | temperature | (gf/cm) | (gf/cm) |
| Example 58 | AGC AN-100 | 250° C. | >1600 | 565 |
| Example 61 | | | >1600 | 685 |
| Example 58 | Corning EXG | | >1600 | 619 |
| Example 61 | | | >1600 | 703 |
| Example 58 | Schott BF33 | | >1600 | 629 |
| Example 61 | | | >1600 | 711 |
| Example 58 | Schott D263 | | >1600 | 602 |
| Example 61 | | | >1600 | 695 |

The results show that the polyimide of the present invention is suitable for various glass substrates, with the peel strength between the polyimide and the glass being greater than 1600 gf/cm, making them impossible to separate, and meeting the requirement for peel strength between the polyimide and metal being greater than 400 gf/cm.

What is claimed is:

1. A modified substrate, comprising:
a substrate selected from the group consisting of a glass substrate, a glass ceramic substrate, and a silicon substrate;
a polyimide layer disposed on at least one surface of the substrate; and
a patterned conductive material disposed on the polyimide layer.

2. The modified substrate according to claim 1, wherein the substrate is a glass substrate and has a plurality of through holes.

3. The modified substrate according to claim 2, wherein the polyimide layer is further disposed on walls of the plurality of through holes.

4. The modified substrate according to claim 1, wherein
the polyimide layer comprises (i) a diamine residue selected from a nitrogen-containing heteroaromatic ring containing at least two nitrogen atoms, an aromatic ring or heterocyclic ring containing at least two —COOH groups, and a combination thereof, and (ii) a 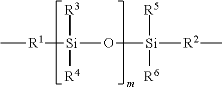
group,
wherein
each of R¹ and R² is independently a C₁-C₄ alkylene group,
each of R³, R⁴, R⁵, and R⁶ is independently H, C₁-C₄ alkyl, or phenyl, and
m is an integer greater than 0.

5. The modified substrate according to claim 4, wherein the polyimide layer has a repeating unit having a structure of formula (II): 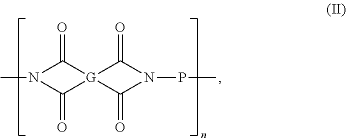
wherein
each G is independently a tetravalent organic group;
n is an integer from 1 to 200; and
each P is independently a divalent organic group, wherein based on the total mole of all divalent organic groups P in the polyimide layer, about 1 mol % to about 20 mol % of the divalent organic groups P are a diamine residue selected from a nitrogen-containing heteroaromatic ring containing at least two nitrogen atoms, an aromatic ring or heterocyclic ring containing at least two —COOH groups, and a combination thereof, and about 0.5 mol % to about 40 mol % of the divalent organic groups P are 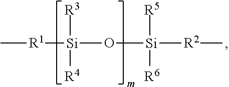
wherein R¹, R², R³, R⁴, R⁵, R⁶, and m have the definition as set forth in claim 4.

6. The modified substrate according to claim 5, wherein
each of R¹ and R² is an n-propylene group,
each of R³, R⁴, R⁵, and R⁶ is independently methyl, and
m is 1.

7. The modified substrate according to claim 4, wherein the diamine residue is selected from 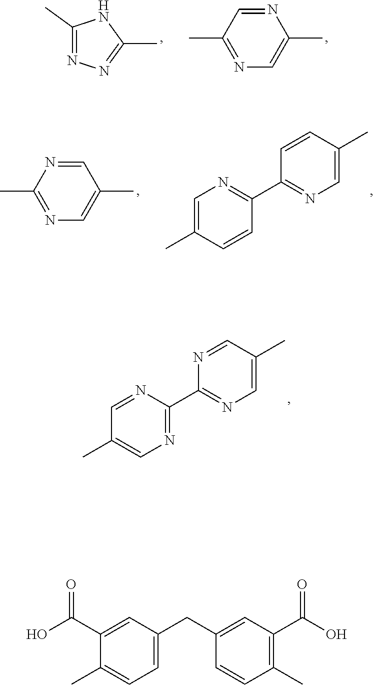
and a combination thereof.

8. A method for manufacturing a modified substrate, comprising:
providing a substrate selected from the group consisting of a glass substrate, a glass ceramic substrate, and a silicon substrate;
applying a polyimide precursor on at least one surface of the substrate, wherein the polyimide layer comprises (i) a diamine residue selected from a nitrogen-containing heteroaromatic ring containing at least two nitrogen atoms, an aromatic ring or heterocyclic ring containing at least two —COOH groups, and a combination thereof, and (ii) a 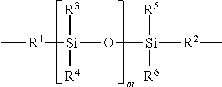
group;
wherein
each of R¹ and R² is independently C₁-C₄ alkyl,
each of R³, R⁴, R⁵, and R⁶ is independently H, C₁-C₄ alkyl, or phenyl, and
m is an integer greater than 0; and
heating at a temperature between about 150° C. and 350° C. to cure the polyimide precursor into a polyimide layer.

9. The method according to claim 8, further comprising applying a patterned conductive material on the surface of the polyimide layer, wherein the peel strength between the polyimide layer and the substrate is 550 gf/cm or more, and the peel strength between the polyimide layer and the conductive material is 400 gf/cm or more.

10. A method of using the modified substrate according to claim 1 as a glass intermediate layer, a silicon intermediate layer, or an IC carrier.
